(19) United States
(12) Patent Application Publication
(10) Pub. No.: US 2011/0049469 A1
(43) Pub. Date: Mar. 3, 2011

(54) Enhanced P-Contacts For Light Emitting Devices

(76) Inventors: Rajaram Bhat, Painted Post, NY (US); Jerome Napierala, Painted Post, NY (US); Dmitry Sizov, Corning, NY (US); Jingqun Xi, Cambridge, MA (US); Chung-En Zah, Holmdel, NJ (US)

(21) Appl. No.: 12/553,288

(22) Filed: Sep. 3, 2009

(51) Int. Cl. H01L 33/00

(52) U.S. Cl. 257/13; 257/E33.008

(57) ABSTRACT

An optoelectronic light emitting semiconductor device is provided comprising an active region, a p-type Group III nitride layer, an n-type Group III nitride layer, a p-side metal contact layer, an n-side metal contact layer, and an undoped tunneling enhancement layer. The p-side metal contact layer is characterized by a work function W satisfying the following relation:

W≦e⁻_{AFF}±0.025 eV

where e⁻_{AFF} is the electron affinity of the undoped tunneling enhancement layer. The undoped tunneling enhancement layer and the p-type Group III nitride layer comprise conduction and valence energy bands. The top of the valence band V1 of the undoped tunneling enhancement layer is above the top of the valence band V2 of the p-type Group III nitride layer at the band offset interface to generate a capacity for a relatively high concentration of holes in the undoped tunneling enhancement layer at the band offset interface. Additional embodiments are disclosed and claimed.

### BACKGROUND

1. Field

The present disclosure relates to optoelectronic light emitting semiconductor devices and, more particularly, to enhanced p-contacts for such devices.

2. Technical Background

The present inventors have recognized that, group III-nitride materials are well-suited for light emitting optoelectronic semiconductor devices including, but not limited to, LEDs and laser diodes. The present inventors have also recognized that it is often difficult to construct effective ohmic p-contacts for these types of light emitting devices because the devices often utilize wafers with crystal surface planes that can be problematic, as is particularly the case for surface planes other than the c-plane. Further, to avoid generating a Schottky barrier for the transport of holes at the interface of the p-contact and the underlying Group III nitride, it would be necessary to select a p-contact metal with a work function larger than or close to the sum of the bandgap and the electron affinity of the associated Group III nitride material. For example, in the case where a p-contact is formed on GaN, the band gap of GaN is 3.4 eV and the electron affinity is 4.1 eV, which would require a p-contact metal with a work function exceeding 7 eV—an excessive requirement given the fact that metal work functions are typically <5.2 eV.

In the context of c-plane GaN, high work function metals, such as Pd, Ni, Pt, and Au can be used as the p-contact metal. However, the present inventors have recognized that these types of metals do not work well outside of the c-plane context because different crystal orientations yield different surface properties, e.g., different surface chemical bonds, different surface electronic states, etc., and the varying surface properties make it difficult to control the characteristics of the Schottky barrier at the p-contact interface. As a result, contact resistivity becomes a function of the surface properties of the GaN material, which can vary depending upon the crystal surface plane of the material. The present disclosure introduces a light emitting structure that can eliminate this variable and obtain an improved p-contact using an enhanced tunneling process. The result is a p-contact that can be applied to any plane of the underlying Group III-nitride material.

### BRIEF SUMMARY

In accordance with various embodiments of the present disclosure, an optoelectronic light emitting semiconductor device is provided comprising an active region, a p-type Group III nitride layer, an n-type Group III nitride layer, a p-side metal contact layer, an n-side metal contact layer, and an undoped tunneling enhancement layer. The active region is interposed between the p-type Group III nitride layer and the n-type Group III nitride layer and is configured to emit light in response to injection of electrons into the active region. The undoped tunneling enhancement layer is interposed between the p-type Group III nitride layer and the p-side metal contact layer to form a metal-semiconductor interface between the metal contact layer and the undoped tunneling enhancement layer and a band offset interface between the undoped tunneling enhancement layer and the p-type Group III nitride layer. The p-side metal contact layer is characterized by a work function W satisfying the following relation to generate a capacity for a relatively high concentration of electron carriers in the undoped tunneling enhancement layer at the metal-semiconductor interface

W≦e⁻_{AFF}±0.025 eV

where e⁻_{AFF} is the electron affinity of the undoped tunneling enhancement layer. The undoped tunneling enhancement layer and the p-type Group III nitride layer comprise conduction and valence energy bands. The top of the valence band V1 of the undoped tunneling enhancement layer is above top of the valence band V2 of the p-type Group III nitride layer at the band offset interface to generate a capacity for a relatively high concentration of holes in the undoped tunneling enhancement layer at the band offset interface.

In accordance with a specific embodiment of the present disclosure: the p-side metal contact layer is characterized by a Fermi level that is within approximately 0.025 eV of or above the bottom of the conduction energy band of the undoped tunneling enhancement layer at the metal-semiconductor interface under equilibrium conditions; the electron affinity e⁻_{AFF} of the undoped tunneling enhancement layer is between approximately 3.8 eV and approximately 5 eV; the work function W of the p-side metal contact layer is less than approximately 4.5 eV; the valence band top of the Group III nitride layer is lower than the top of the valence band of the undoped tunneling enhancement layer at the band offset interface; the undoped tunneling enhancement layer comprises a thickness of less than approximately 20 nm; and the relatively high concentration of electron carriers generated in the undoped tunneling enhancement layer at the metal-semiconductor interface and the relatively high concentration of holes generated in the undoped tunneling enhancement layer at the band offset interface reduce a corresponding effective tunneling length in the undoped tunneling enhancement layer to a value that is smaller than the thickness of the undoped tunneling enhancement layer.

### BRIEF DESCRIPTION OF THE SEVERAL VIEWS OF THE DRAWINGS

The following detailed description of specific embodiments of the present disclosure can be best understood when read in conjunction with the following drawings, where like structure is indicated with like reference numerals and in which:

FIG. 1 is a schematic illustration of one type of an optoelectronic light emitting semiconductor device incorporating the enhanced p-contact of the present disclosure;

FIG. 2 is a band diagram illustrating the characteristics of one type of enhanced p-contact of the present disclosure; and

FIG. 3 is graphical representation of the distribution of electron carriers and holes in a undoped tunneling enhancement layer of an optoelectronic light emitting semiconductor device incorporating the enhanced p-contact of the present disclosure.

### DETAILED DESCRIPTION

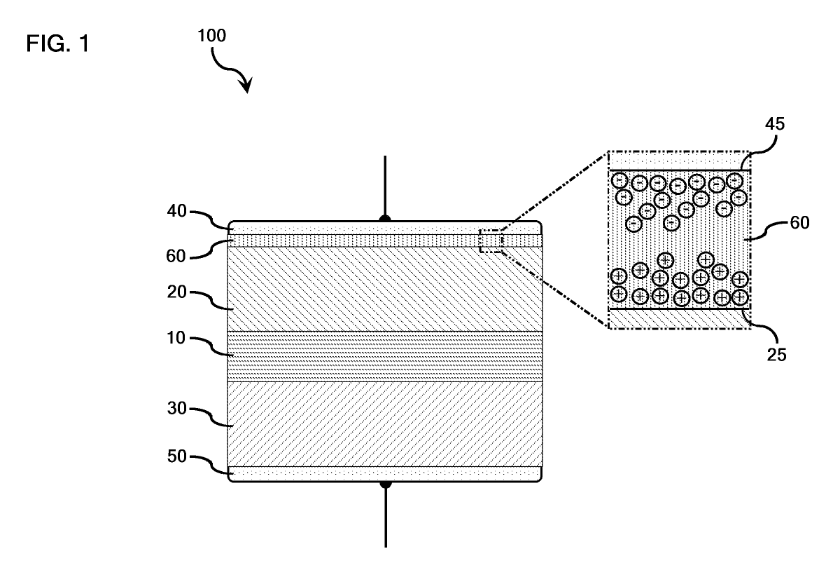

FIG. 1 illustrates one type of optoelectronic light emitting semiconductor device employing an enhanced p-contact according to the present disclosure. More specifically, FIG. 1 illustrates an enhanced p-contact in the context of a laser diode wafer 100 comprising a mulit-quantum well active region 10, a p-type Group III nitride layer 20, an n-type Group III nitride layer 30, a p-side metal contact layer 40, an n-side metal contact layer 50, and an undoped tunneling enhancement layer 60. As will be appreciated by those practicing the technology disclosed herein the concepts of the present disclosure will be applicable to a variety of light emitting semiconductor devices including, but not limited to, conventional and yet to be developed configurations for laser diodes and light emitting diodes.

As is illustrated in FIG. 1, the active region 10 is interposed between the p-type Group III nitride layer 20 and the n-type Group III nitride layer 30 and is configured to emit light in response to injection of electrons into the active region 10. The undoped tunneling enhancement layer 60 is interposed between the p-type Group III nitride layer 20 and the p-side metal contact layer 40 to form a metal-semiconductor interface 45 between the metal contact layer 40 and the undoped tunneling enhancement layer 60 and a band offset interface 25 between the undoped tunneling enhancement layer 60 and the p-type Group III nitride layer 20.

To generate the capacity for a relatively high concentration of electron carriers in the undoped tunneling enhancement layer 60 at the metal-semiconductor interface 45, the work function W of the p-side metal contact layer 40 should satisfy the following relation:

W≦e⁻_{AFF}±0.025 eV

where e⁻_{AFF} is the electron affinity of the undoped tunneling enhancement layer 60. Those practicing the present technology may find it useful to ensure that the electron affinity e⁻_{AFF} of the undoped tunneling enhancement layer 60 is between approximately 3.8 eV and approximately 5 eV and the work function W of the p-side metal contact layer 20 is less than approximately 4.5 eV. The electron affinity e⁻_{AFF} of the undoped tunneling enhancement layer and the work function W of the p-side metal contact layer are such that the metal-semiconductor interface does not support a Schottky barrier.

Although the p-side metal contact layer 40 may be formed from a variety of conductive materials, it is noted for illustrative purposes that Ti, In, Zn, Mg, or alloys thereof are suitable candidates. Conductive metal oxides such as indium-tin oxide are also contemplated. Typically, the work function W of the p-side metal contact layer is less than approximately 4.5 eV. Stated more generally, the work function W of the p-side metal contact layer should be closer to that of metals like Ti, In, Zn, and Mg than it is to metals like Pd, Ni, Pt, and Au.

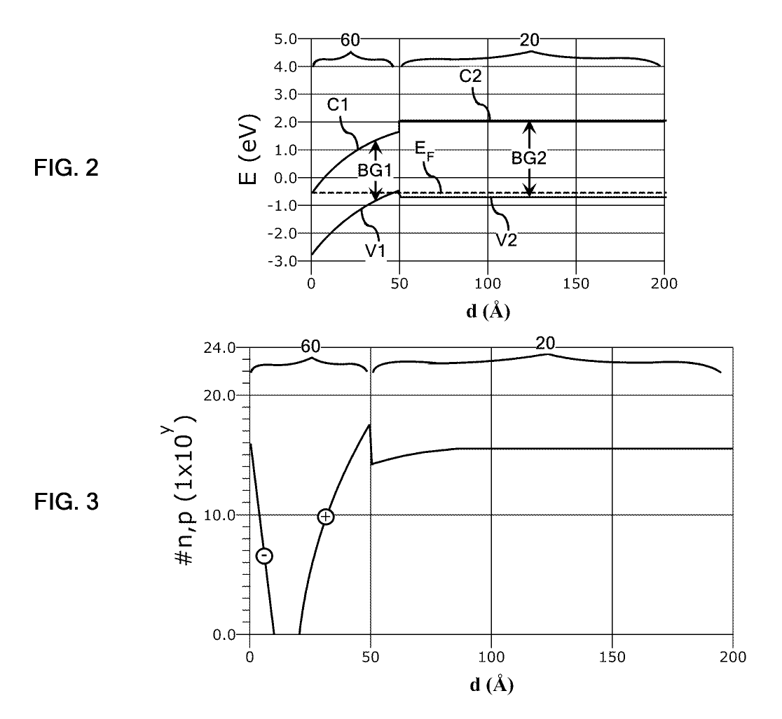

Further, to generate the capacity for a relatively high concentration of holes in the undoped tunneling enhancement layer 60 at the band offset interface 25. Referring to FIG. 2, the undoped tunneling enhancement layer 60 and the p-type Group III nitride layer 20 each comprise conduction and valence energy bands with corresponding tops/bottoms labeled respectively as C1, V1, C2, V2. These bands define corresponding energy bandgaps BG1, BG2 there between. To help generate a capacity for a relatively high concentration of holes in the undoped tunneling enhancement layer at the band offset interface, the top of the valence band V1 of the undoped tunneling enhancement layer is above the top of the valence band V2 of the p-type Group III nitride layer at the band offset interface. In practice, it will often be preferable to ensure that the valence band top V2 of the Group III nitride layer is at least approximately 100 meV lower than the valence band top V1 to activate acceptors from the Group III nitride layer 20, but care should be taken to ensure that the top of the valence energy band V2 is not so low that it generates an additional barrier.

In the embodiment illustrated in FIG. 2, the energy bandgap BG1 of the undoped tunneling enhancement layer 60 is located entirely within the energy bandgap BG2 of the Group III nitride layer 20. In some cases, it may merely be preferable to ensure that the energy bandgap of the undoped tunneling enhancement layer is less than the energy bandgap of the Group III nitride layer.

The aforementioned relatively high concentrations of electron carriers and holes at the two opposing interfaces of the undoped tunneling enhancement layer 60 are illustrated schematically in FIG. 1 and graphically in FIG. 3. The relatively high concentration of electron carriers generated in the undoped tunneling enhancement layer 60 at the metal-semiconductor interface 45 and the relatively high concentration of holes generated in the undoped tunneling enhancement layer at the band offset interface 25 reduce the corresponding effective tunneling length in the undoped tunneling enhancement layer 60 to a value that is smaller than the thickness of the undoped tunneling enhancement layer 60. As a result, the enhanced p-contact of the present disclosure can be used to ensure that the metal-semiconductor interface 45 does not support a Schottky barrier.

Although it is contemplated that a wide range of thicknesses may be suitable for enhancing the p-contact, it is noted that the undoped tunneling enhancement layer 60 comprises a thickness of less than approximately 20 nm or, more narrowly, a thickness of less than approximately 50 Å. In particular embodiments of the present disclosure, the undoped tunneling enhancement layer 60 comprises a group III nitride. Suitable group III nitrides include, but are not limited to, Ga, In, Al, or combinations thereof, such as InGaN, InAlN, AlGaN, GaN, InAlGaN, etc.

As is illustrated in FIG. 2, the p-side metal contact layer 40 is characterized by a Fermi level E_{F} that is approximately equal to or up to approximately 2 eV higher than the bottom of the conduction energy band of the undoped tunneling enhancement layer 60 at the metal-semiconductor interface 45 under equilibrium conditions. In some cases, it may be sufficient to merely ensure that the Fermi level that is within approximately 1 eV of the bottom of the conduction energy band.

It is noted that recitations herein of a component of the present disclosure being “configured” to embody a particular property, or function in a particular manner, are structural recitations, as opposed to recitations of intended use. More specifically, the references herein to the manner in which a component is “configured” denotes an existing physical condition of the component and, as such, is to be taken as a definite recitation of the structural characteristics of the component.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

For the purposes of describing and defining the present invention, it is noted that the term “approximately” is utilized herein to represent the inherent degree of uncertainty that may be attributed to any quantitative comparison, value, measurement, or other representation.

Having described the subject matter of the present disclosure in detail and by reference to specific embodiments thereof, it will be apparent that modifications and variations are possible without departing from the scope of the invention defined in the appended claims. More specifically, although some aspects of the present disclosure are identified herein as preferred or particularly advantageous, it is contemplated that the present disclosure is not necessarily limited to these aspects.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

1. An optoelectronic light emitting semiconductor device comprising an active region, a p-type Group III nitride layer, an n-type Group III nitride layer, a p-side metal contact layer, an n-side metal contact layer, and a undoped tunneling enhancement layer, wherein:
the active region is interposed between the p-type Group III nitride layer and the n-type Group III nitride layer and is configured to emit light in response to injection of electrons into the active region;
the undoped tunneling enhancement layer is interposed between the p-type Group III nitride layer and the p-side metal contact layer to form a metal-semiconductor interface between the metal contact layer and the undoped tunneling enhancement layer and a band offset interface between the undoped tunneling enhancement layer and the p-type Group III nitride layer;
the p-side metal contact layer is characterized by a work function W satisfying the following relation to generate a capacity for a relatively high concentration of electron carriers in the undoped tunneling enhancement layer at the metal-semiconductor interface
W≦e⁻_{AFF}±0.025 eV
where e⁻_{AFF} is the electron affinity of the undoped tunneling enhancement layer;
the undoped tunneling enhancement layer and the p-type Group III nitride layer comprise conduction and valence energy bands; and
the top of the valence band V1 of the undoped tunneling enhancement layer is above the top of the valence band V2 of the p-type Group III nitride layer at the band offset interface to generate a capacity for a relatively high concentration of holes in the undoped tunneling enhancement layer at the band offset interface.

2. An optoelectronic light emitting semiconductor device as claimed in claim 1 wherein:
the p-side metal contact layer is characterized by a Fermi level that is above the bottom of the conduction energy band of the undoped tunneling enhancement layer at the metal-semiconductor interface under equilibrium conditions;
the electron affinity e⁻_{AFF} of the undoped tunneling enhancement layer is between approximately 3.8 eV and approximately 5 eV;
the work function W of the p-side metal contact layer is less than approximately 4.5 eV;
the undoped tunneling enhancement layer comprises a thickness of less than approximately 20 nm; and
the relatively high concentration of electron carriers generated in the undoped tunneling enhancement layer at the metal-semiconductor interface and the relatively high concentration of holes generated in the undoped tunneling enhancement layer at the band offset interface reduce a corresponding effective tunneling length in the undoped tunneling enhancement layer to a value that is smaller than the thickness of the undoped tunneling enhancement layer.

3. An optoelectronic light emitting semiconductor device as claimed in claim 1 wherein the p-side metal contact layer is characterized by a Fermi level that is approximately equal to the bottom of the conduction energy band of the undoped tunneling enhancement layer at the metal-semiconductor interface under equilibrium conditions.

4. An optoelectronic light emitting semiconductor device as claimed in claim 1 wherein the p-side metal contact layer is characterized by a Fermi level that is approximately equal to or up to approximately 2 eV higher than the bottom of the conduction energy band of the undoped tunneling enhancement layer at the metal-semiconductor interface under equilibrium conditions.

5. An optoelectronic light emitting semiconductor device as claimed in claim 1 wherein the p-side metal contact layer is characterized by a Fermi level that is within approximately 1 eV of the bottom of the conduction energy band of the undoped tunneling enhancement layer at the metal-semiconductor interface under equilibrium conditions.

6. An optoelectronic light emitting semiconductor device as claimed in claim 1 wherein:
the electron affinity e⁻_{AFF} of the undoped tunneling enhancement layer is between approximately 3.8 eV and approximately 5 eV; and
the work function W of the p-side metal contact layer is less than approximately 4.5 eV.

7. An optoelectronic light emitting semiconductor device as claimed in claim 1 wherein the electron affinity e⁻_{AFF} of the undoped tunneling enhancement layer and the work function W of the p-side metal contact layer are such that the metal-semiconductor interface does not support a Schottky barrier.

8. An optoelectronic light emitting semiconductor device as claimed in claim 1 wherein the top of the valence energy band of the Group III nitride layer is at least approximately 0.1 eV lower than the top of the valence energy band of the undoped tunneling enhancement layer at the band offset interface.

9. An optoelectronic light emitting semiconductor device as claimed in claim 1 wherein the energy bandgap of the undoped tunneling enhancement layer is located entirely within the energy bandgap of the Group III nitride layer.

10. An optoelectronic light emitting semiconductor device as claimed in claim 1 wherein the energy bandgap of the undoped tunneling enhancement layer is less than the energy bandgap of the Group III nitride layer.

11. An optoelectronic light emitting semiconductor device as claimed in claim 1 wherein the relatively high concentration of electron carriers generated in the undoped tunneling enhancement layer at the metal-semiconductor interface and the relatively high concentration of holes generated in the undoped tunneling enhancement layer at the band offset interface reduce a corresponding effective tunneling length in the undoped tunneling enhancement layer to a value that is smaller than the thickness of the undoped tunneling enhancement layer.

12. An optoelectronic light emitting semiconductor device as claimed in claim 1 wherein the undoped tunneling enhancement layer comprises a thickness of less than approximately 20 nm.

13. An optoelectronic light emitting semiconductor device as claimed in claim 1 wherein the undoped tunneling enhancement layer comprises a thickness of less than approximately 50 Å.

14. An optoelectronic light emitting semiconductor device as claimed in claim 1 wherein the undoped tunneling enhancement layer comprises a group III nitride.

15. An optoelectronic light emitting semiconductor device as claimed in claim 14 wherein the group III nitride comprises Ga, In, Al, or combinations thereof.

16. An optoelectronic light emitting semiconductor device as claimed in claim 14 wherein the group III nitride comprises InGaN.

17. An optoelectronic light emitting semiconductor device as claimed in claim 14 wherein the group III nitride comprises InAlN.

18. An optoelectronic light emitting semiconductor device as claimed in claim 1 wherein the p-side metal contact layer comprises Ti, In, Zn, Mg, or alloys thereof.

19. An optoelectronic light emitting semiconductor device as claimed in claim 1 wherein the work function W of the p-side metal contact layer is less than approximately 4.5 eV.

20. An optoelectronic light emitting semiconductor device as claimed in claim 1 wherein the work function W of the p-side metal contact layer is closer to that of metals like Ti, In, Zn, and Mg than metals like Pd, Ni, Pt, and Au.
